(19) United States
(12) Patent Application Publication
(10) Pub. No.: US 2017/0047310 A1
(43) Pub. Date: Feb. 16, 2017

(54) SEMICONDUCTOR PACKAGE AND METHOD OF MANUFACTURING THE SAME

(71) Applicant: Samsung Electronics Co., Ltd., Suwon-si (KR)

(72) Inventors: Jong-Bo SHIM, Asan-si (KR); Seung-Duk BAEK, Hwaseong-si (KR); Cha-Jea JO, Yongin-Si (KR); Tae-Je CHO, Yongin-si (KR)

(21) Appl. No.: 15/183,778

(22) Filed: Jun. 15, 2016

(30) Foreign Application Priority Data
Aug. 13, 2015 (KR) 10-2015-0114234

(51) Int. Cl. H01L 25/065; H01L 21/78; H01L 23/544; H01L 25/00

(52) U.S. Cl. CPC H01L 25/0657; H01L 25/50; H01L 21/78; H01L 23/544; H01L 2225/06513; H01L 2225/06544; H01L 2225/06555; H01L 2225/06582; H01L 2225/06593; H01L 2223/5446

(57) ABSTRACT

A semiconductor package may include a package substrate, a semiconductor chip and a molding member. A protrusion may be formed on a side surface of the package substrate. The semiconductor chip may be arranged on an upper surface of the package substrate. The semiconductor chip may be electrically connected with the package substrate. The molding member may be formed on the upper surface and the side surface of the package substrate, and an upper surface of the protrusion. Thus, the molding member on the protrusion of the package substrate may be configured to cover the side surface of the package substrate so that the side surface of the package substrate may not be exposed.

### CROSS-RELATED APPLICATION

This application claims priority under 35 U.S.C. §119 to Korean Patent Application No. 2015-0114234, filed on Aug. 13, 2015 in the Korean Intellectual Property Office (KIPO), the contents of which are herein incorporated by reference in their entirety.

### BACKGROUND

1. Field

Example embodiments relate to a semiconductor package and a method of manufacturing the same. More particularly, example embodiments relate to a semiconductor chip including sequentially stacked semiconductor chips, and a method of manufacturing the semiconductor package.

2. Description of the Related Art

Generally, a semiconductor package may include a package substrate, a semiconductor chip, a conductive connecting member and a molding member. The semiconductor chip may be arranged on an upper surface of the package substrate. The conductive connecting member may electrically connect the semiconductor chip with the package substrate. The molding member may be formed on the package substrate to cover the semiconductor chip.

In some cases, a side surface of the package substrate may not be covered with the molding member. Thus, the side surface of the package substrate may be exposed. The exposed side surface of the package substrate may be damaged electrically, physically and/or chemically.

### SUMMARY

Example embodiments provide a semiconductor package that may be capable of suppressing a side surface of the package substrate from being damaged.

Example embodiments also provide a method of manufacturing the above-mentioned semiconductor package.

According to example embodiments, there may be provided a semiconductor package. The semiconductor package may include a package substrate, a semiconductor chip and a molding member. A protrusion may be formed on a side surface of the package substrate. The semiconductor chip may be arranged on an upper surface of the package substrate. The semiconductor chip may be electrically connected with the package substrate. The molding member may be formed on the upper surface and the side surface of the package substrate, and an upper surface of the protrusion.

In example embodiments, the protrusion may be formed on a lower portion of the side surface of the package substrate.

In example embodiments, the protrusion may have a slant side surface.

In example embodiments, a portion of the molding member on the upper surface of the protrusion may have a slant side surface that is substantially coplanar with the slant side surface of the protrusion.

In example embodiments, the molding member may have an outer surface protruded from an outer surface of the protrusion.

In example embodiments, the molding member may include an inner molding portion configured to surround the semiconductor chip, and an outer molding portion formed on the upper surface and the side surface of the package substrate, and the upper surface of the protrusion to surround the inner molding portion.

In example embodiments, the inner molding portion may include a first insulating material. The outer molding portion may include a second insulating material that is different from the first insulating material.

In example embodiments, the semiconductor chip may include a plug formed in the semiconductor chip. The semiconductor package may further include a second semiconductor chip stacked on the semiconductor chip, and a conductive bump interposed between the semiconductor chip and the second semiconductor chip to electrically connect the plug with the second semiconductor chip.

According to example embodiments, there may be provided a method of manufacturing a semiconductor package. In the method of manufacturing the semiconductor package, a plurality of first semiconductor chips may be arranged on an upper surface of a wafer. A receiving groove may be formed at a portion of the wafer between the first semiconductor chips. A space between the first semiconductor chips and the receiving groove may be filled with a molding member. A portion of the wafer under the receiving groove and a portion of the molding member in the receiving groove may be removed to form a notch. The molding member may be cut along the notch.

In example embodiments, the method may further include attaching the wafer to a supporting substrate, and separating the supporting substrate from the wafer before forming the notch.

In example embodiments, the notch may have an inverse V shape.

In example embodiments, the inverse V-shaped notch may have a lower width that is greater than a width at a vertex of the V-shaped notch.

In example embodiments, the method may further include surrounding the first semiconductor chip with an inner molding member.

In example embodiments, the method may further include stacking a second semiconductor chip on the first semiconductor chip.

In example embodiments, stacking the second semiconductor chip on the first semiconductor chip may include electrically connecting a plug of the first semiconductor chip with the second semiconductor chip using a conductive bump.

According to example embodiments, there may be provides a semiconductor package that includes a package substrate comprising an upper surface, a first side and a second side that is opposite the first side in which the first side comprises a first protuberance that extends from the first side in a direction that is substantially parallel to the upper surface of the package substrate, and the second side comprises a second protuberance that extends from the second side in a direction that is substantially parallel to the upper surface of the package substrate, and in which the first and second protuberances each comprise an upper surface. A first semiconductor chip may be disposed on the upper surface of the package substrate. A mold member may be formed on the upper surface of the package substrate to cover the upper surface, the first side and the second side of the package substrate and the upper surface of each of the first and second protuberances.

In example embodiments, the first and second protuberances each comprise an edge surface that is angled with respect to the upper surface of the package substrate.

In example embodiments, the mold member may comprise a first surface that is substantially coplanar with the angled edge surface of the first protuberance and a second surface that is substantially coplanar with the angle edge of the second protuberance.

In example embodiments, the molding member may comprise a first molding portion and a second molding portion in which the first molding portion is configured to surround the first semiconductor chip and the second molding portion is configured to surround the first molding portion.

In example, embodiments, the first semiconductor chip may be electrically connected to the package substrate by at least one conductive bump.

In example, embodiments, the first semiconductor chip may be electrically connected to the package substrate by at least one conductive wire.

In example embodiments, the semiconductor package may further comprise a second semiconductor chip formed disposed on the first semiconductor chip.

In example embodiments, the first semiconductor chip may comprise at least one conductive plug formed through the first semiconductor chip, and the second semiconductor chip may be electrically connected to the at least one conductive plug by a conductive bump interposed between the first semiconductor chip and the second semiconductor chip.

In example embodiments, the first semiconductor chip may be electrically connected to the package substrate by at least one conductive bump.

In example embodiments, the mold member may be further formed to cover the first and second semiconductor chips.

According to example embodiments, the molding member on the protrusion of the package substrate may be configured to cover the side surface of the package substrate so that the side surface of the package substrate may not be exposed. Thus, electrical, physical and/or chemical damages to the side surface of the package substrate may be suppressed.

### BRIEF DESCRIPTION OF THE DRAWINGS

Example embodiments will be more clearly understood from the following detailed description taken in conjunction with the accompanying drawings. FIGS. 1 to 21 represent non-limiting, example embodiments as described herein.

FIG. 1 is a cross-sectional view illustrating a semiconductor package in accordance with example embodiments;

FIG. 2 is an enlarged cross-sectional view of a portion II in FIG. 1;

FIGS. 3 to 7 are cross-sectional views illustrating a method of manufacturing the semiconductor package in FIG. 1;

FIG. 8 is a cross-sectional view illustrating a semiconductor package in accordance with example embodiments;

FIGS. 9 to 13 are cross-sectional views illustrating a method of manufacturing the semiconductor package in FIG. 8;

FIG. 14 is a cross-sectional view illustrating a semiconductor package in accordance with example embodiments;

FIGS. 15 to 20 are cross-sectional views illustrating a method of manufacturing the semiconductor package in FIG. 14;

FIG. 21 is a cross-sectional view illustrating a semiconductor package in accordance with example embodiments;

FIG. 22 is a block diagram schematically illustrating an electronic circuit board including a semiconductor package according to an example embodiment; and

FIG. 23 is a block diagram schematically illustrating an electronic system according to an example embodiment disclosed herein.

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Additionally, the terms “horizontal” or “horizontally,” as used herein, generally refer to a direction that is substantially parallel to the x-axis, as indicated in the FIGS. Similarly, the terms “vertical” or “vertically,” as used herein, generally refer to a direction that is substantially parallel to the y-axis, as indicted in the FIGS.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

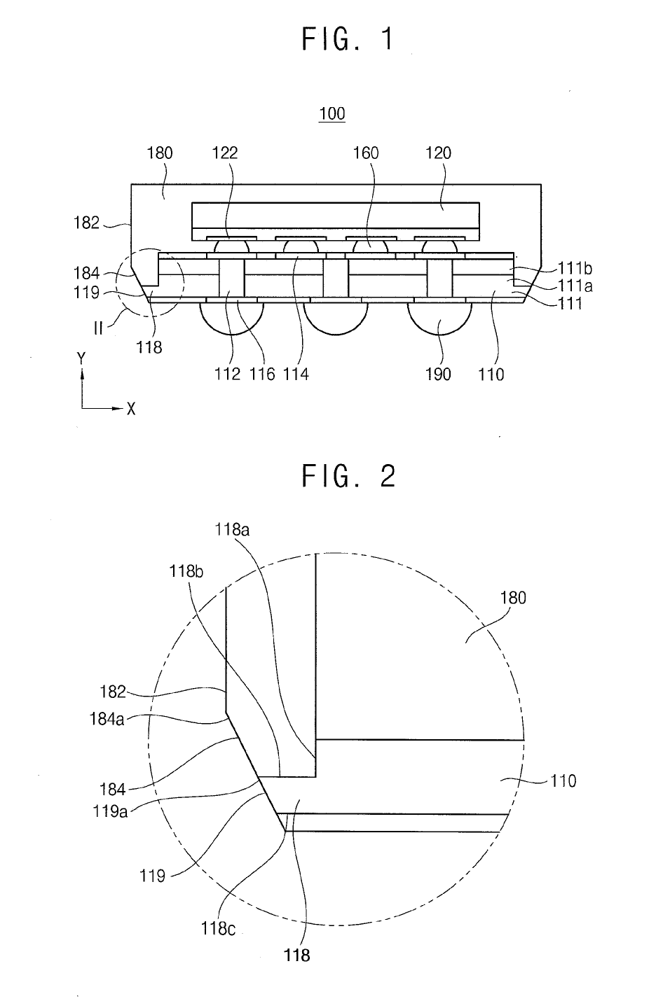

FIG. 1 is a cross-sectional view illustrating a semiconductor package in accordance with example embodiments, and FIG. 2 is an enlarged cross-sectional view of a portion II in FIG. 1.

Referring to FIGS. 1 and 2, a semiconductor package 100 of this example embodiment may include a package substrate 110, a semiconductor chip 120, conductive bumps 160, a molding member 180 and external terminals 190. The semiconductor package 100 may include a high-band width memory package.

The package substrate 110 may include an insulating substrate 111, a contact 112, an upper pad 114 and a lower pad 116. In one embodiment, the package substrate 110 may include one or more insulating substrates, as depicted in the figures as insulating substrates 111a and 111b. The contact 112 may be formed vertically within the insulating substrate 111. That is, contact 112 may be formed to be a through via that extends through the insulating substrate 111 in the y direction. The upper pad 114 may be arranged on an upper surface of the insulating substrate 111. The upper pad 114 may be electrically connected to the contact 112. The lower pad 116 may be arranged on a lower surface of the insulating substrate 111. The lower pad 116 may be electrically connected to the contact 112.

The package substrate 110 may include a protrusion 118. In one embodiment, the protrusion 118 may be formed from an entire side surface of the package substrate 110 in a horizontal direction. That is, the protrusion 118 may be formed to extend in a horizontal direction (i.e., substantially parallel to the x-axis) so that a thickness of the protrusion 118 in a vertical direction (i.e., substantially parallel to the y-axis) may be substantially equal to a thickness in the vertical direction of the package substrate 111. In an alternative embodiment, the protrusion 118 may be formed on a lower portion of the side surface of the package substrate 110. That is, the protrusion 118 may be formed to extend horizontally (i.e., substantially parallel to the x-axis) from a lower portion of the package substrate 110 so that a thickness of the protrusion 118 in a vertical direction (i.e., substantially parallel to the y-axis) may be less than the thickness in the vertical direction of the package substrate 111. Thus, the protrusion 118 may have an exposed upper surface 118a. In contrast, because the protrusion 118 may be positioned on the lower portion of the side surface of the package substrate 110, only an upper portion 118a of the side surface of the package substrate 110 may be exposed. Further, the protrusion 118 may have a slant side surface 119. The slant side surface 119 may have an inclined direction with respect to the Cartesian axes indicated in FIG. 1 for providing the upper surface 118b of the protrusion 118 with an area larger than a lower surface 118c of the protrusion 118. Thus, the protrusion 118 may have a gradually increasing width from the lower surface 118c to the upper surface 118b.

The semiconductor chip 120 may be arranged on the upper surface of the package substrate 110. The semiconductor chip 120 may include bonding pads 122. The bonding pads 122 may be arranged on a lower surface of the semiconductor chip 120. Thus, the lower surface of the semiconductor chip 120 may correspond to an active face of the semiconductor chip 120.

The conductive bumps 160 may be interposed between the semiconductor chip 120 and the package substrate 110. The conductive bumps 160 may make contact with the bonding pads 122 and the upper pad 114 to electrically connect the semiconductor chip 120 with the package substrate 110.

The molding member 180 may be formed on the upper surface and the side surface of the package substrate 110 and the upper surface 118b of the protrusion 118 to cover the semiconductor chip 120. Thus, the molding member 180 may be configured to cover the side surface of the package substrate 110 to prevent the side surface of the package substrate 110 from being exposed. The molding member 180 may include an organic material, an epoxy molding compound (EMC).

A portion of the molding member 180 on the upper surface 118b of the protrusion 118 may have a slant side surface 184. The slant side surface 184 of the molding member 180 may be substantially coplanar with the slant side surface 119 of the protrusion 118. The slant side surface 184 of the molding member 180 may have an upper end 184a outside an upper end 119a of the slant side surface 119 of the protrusion 118. That is, the slant side surface 184 may extend beyond the upper end 119a of the slant side surface 119.

The molding member 180 may have an outer surface 182 vertically extended from the upper end 184a of the slant side surface 184 of the molding member 180. As mentioned above, because the upper end 184a of the slant side surface 184 of the molding member 180 may be located outside the upper end 119a of the slant side surface 119 of the protrusion 118, the outer surface 182 of the molding member 180 may protrude from the slant side surface 119 of the protrusion 118. Therefore, although the exposed slant side surface 119 of the protrusion 118 may not be directly protected by the molding member 180, the outer surface 182 of the molding member 180 protruding from the slant side surface 119 of the protrusion 118 may indirectly protect the exposed slant side surface 119 of the protrusion 118.

The external terminals 190 may be mounted on the lower pads 116 of the package substrate 110. The external terminals 190 may include solder balls.

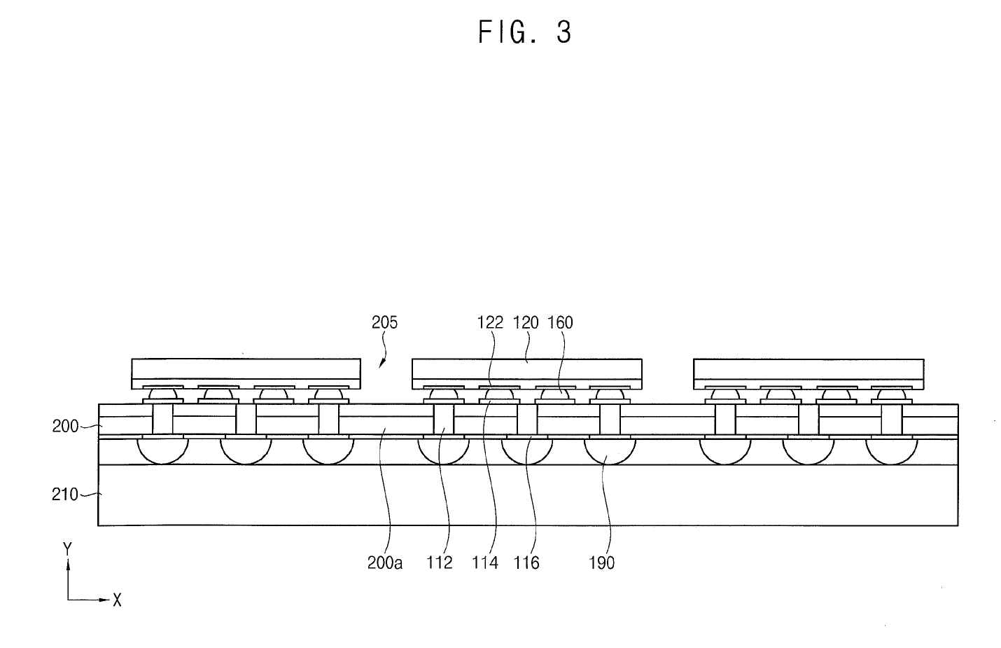

FIGS. 3 to 7 are cross-sectional views illustrating a method of manufacturing the semiconductor package in FIG. 1.

Referring to FIG. 3, the semiconductor chip 120 may be attached to an upper surface of a wafer 200 using the conductive bumps 160. The wafer 200 may correspond to the package substrate 110 shown in FIG. 1. The wafer 200 may include the contacts 112, the upper pads 114 and the lower pads 116. The wafer 200 may be cut along scribe lanes 205 by the following processes to form the package substrates 110. The external terminals 190 may be mounted on the lower pads 116 of the wafer 200.

The wafer 200 may be attached to an upper surface of a supporting substrate 210. The supporting substrate 210 may function to support the wafer 200 in the following processes. The supporting substrate 210 may include a bare wafer.

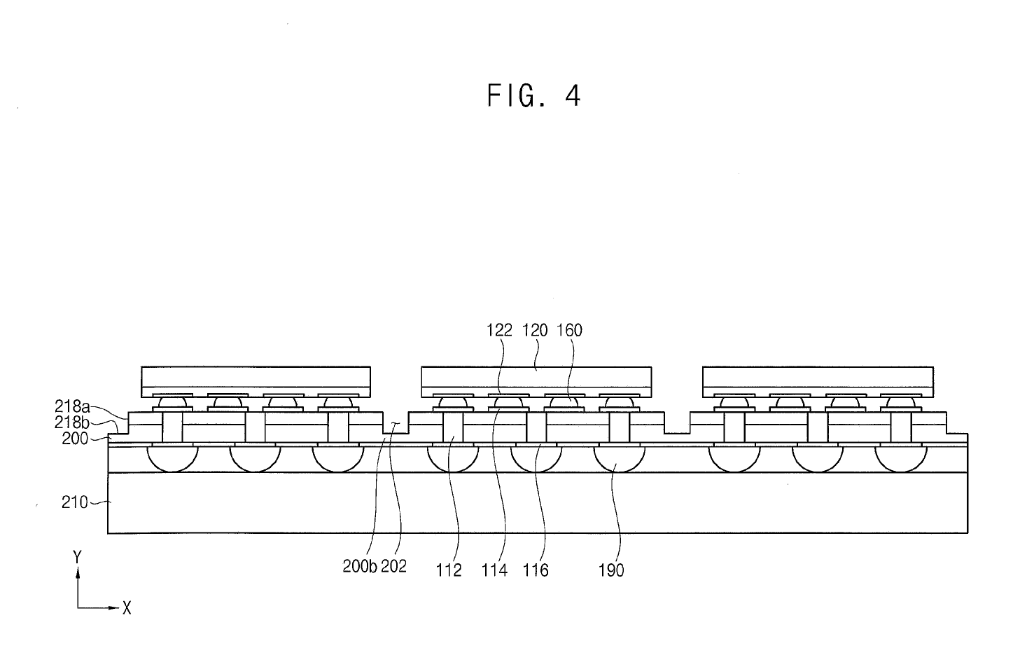

Referring to FIG. 4, portions 200a (FIG. 3) of the wafer 200 between the semiconductor chips 120 may be partially cut to form receiving grooves 202. Each of receiving grooves 202 may have a depth in the vertical direction that is less than a thickness of the wafer 200 in a vertical direction. Thus, side surfaces 218a of the wafer 200 may be exposed through the receiving grooves 202. The each of exposed side surfaces 218a of the wafer 200 may correspond to the side surface 118a of the package substrate 110. Portions of the wafer 200 in a lower space 218b of each of the receiving grooves 202 may remain. The receiving grooves 202 may be formed by a cutting process using a blade, a laser, etc., or an etching process. The supporting substrate 210 may firmly support the wafer 200 in forming the receiving grooves 202.

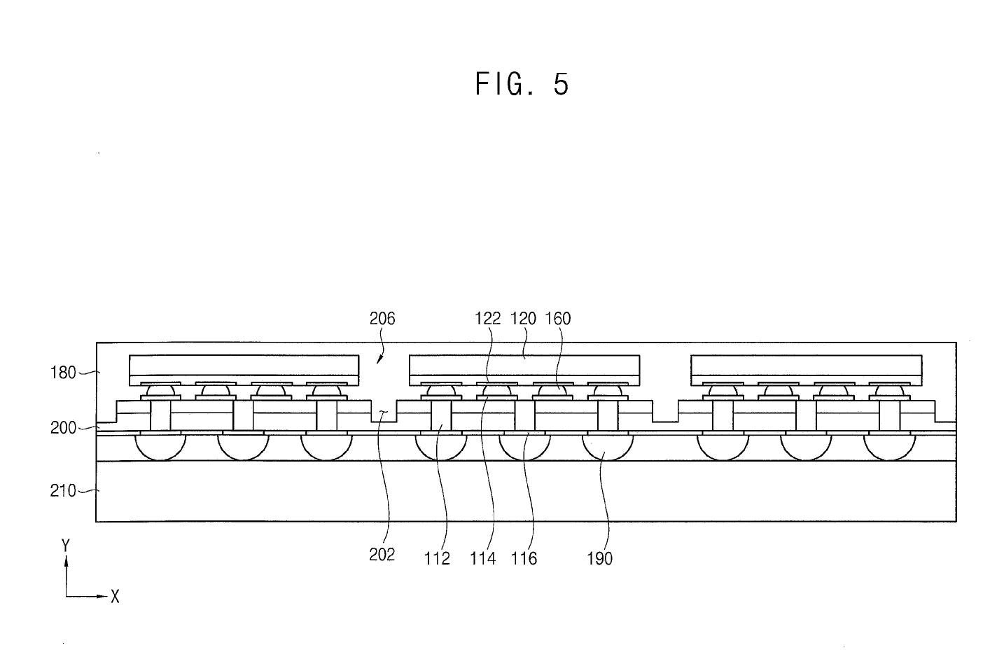

Referring to FIG. 5, the molding member 180 may be formed on the upper surface of the wafer 200. The molding member 180 may be configured to cover the semiconductor chips 120. The molding member 180 may be configured to fill up spaces 206 between the semiconductor chips 120 and the receiving grooves 202. Because the molding member 180 may firmly support the semiconductor chips 120 and the wafer 200, the supporting substrate 210 may be separated from the wafer 200.

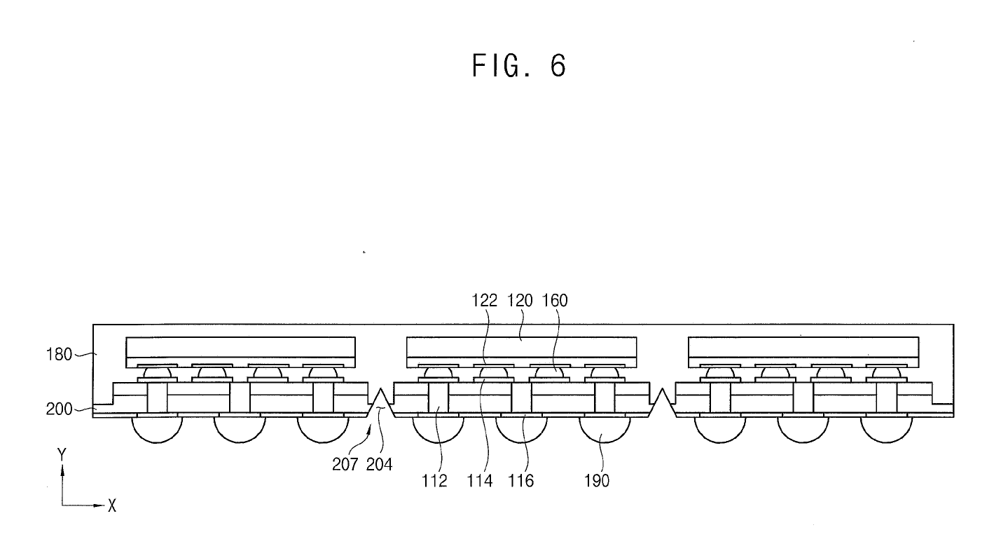

Referring to FIG. 6, after separating the supporting substrate 210 from the wafer 200, the portions of the wafer 200 in the lower spaces of receiving grooves 202 may be exposed at 207. The portions 200b (FIG. 4) of the wafer 200 in the lower spaces of the receiving grooves 202 and the molding member 180 in the receiving grooves 202 may be removed to form notches 204.

Each of the notches 204 may have an inverse V shape. Thus, the notch 204 may have a width in the horizontal direction that gradually decreases from a lower end to an upper end in the notch 204. That is, the width in the horizontal direction of the lower portion of the notch 204 may be wider than a width of the receiving groove 202 at the vertex of the V shape. The protrusions 118 (FIGS. 1 and 2) may be formed on the side surfaces of the wafer 200 by forming the inverse V-shaped notches 204. An inner surface of the inverse V-shaped notch 204 may correspond to the slant side surface 119 (FIGS. 1 and 2) of the protrusion 118 and the slant side surface 184 of the molding member 180.

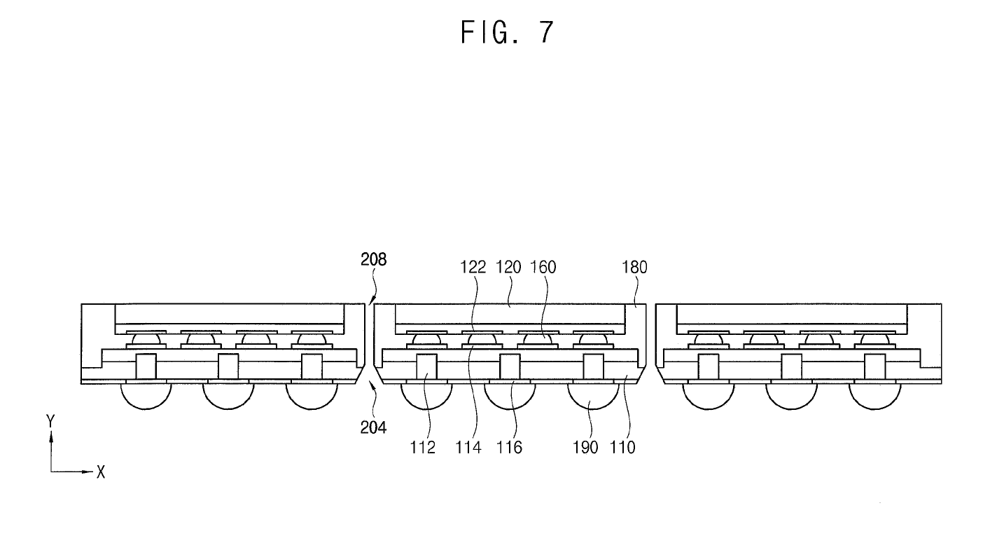

Referring to FIG. 7, the molding member 180 may be cut in the vertical direction at 208 from the upper end of the notch 204 to complete the semiconductor package 100 in FIG. 1.

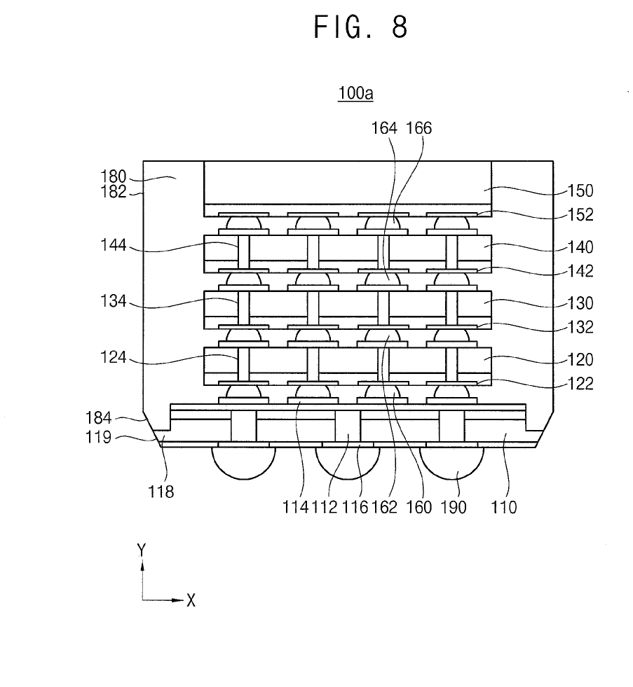

FIG. 8 is a cross-sectional view illustrating a semiconductor package in accordance with example embodiments.

A semiconductor package 100a of this example embodiment may include elements substantially the same as those of the semiconductor package 100 in FIG. 1, except for further including second to fourth semiconductor chips. Thus, the same reference numerals may refer to the same elements and any further descriptions with respect to the same elements may be omitted herein for brevity.

Referring to FIG. 8, the semiconductor chip 120 may include plugs 124. The plugs 124 may be vertically formed through in the semiconductor chip 120. The plugs 124 may be electrically connected to the bonding pads 122.

A second semiconductor chip 130 may be stacked on an upper surface of the semiconductor chip 120. The second semiconductor chip 130 may include second bonding pads 132 and second plugs 134. The second bonding pads 132 may be arranged on a lower surface of the second semiconductor chip 130. The second plugs 134 may be vertically formed through the second semiconductor chip 130. The second plugs 134 may be electrically connected to the second bonding pads 132. The second bonding pads 132 may be electrically connected with the plugs 124 via second conductive bumps 162.

A third semiconductor chip 140 may be stacked on an upper surface of the second semiconductor chip 130. The third semiconductor chip 140 may include third bonding pads 142 and third plugs 144. The third bonding pads 142 may be arranged on a lower surface of the third semiconductor chip 140. The third plugs 144 may be vertically formed through the third semiconductor chip 140. The third plugs 144 may be electrically connected to the third bonding pads 142. The third bonding pads 142 may be electrically connected with the second plugs 134 via third conductive bumps 164.

A fourth semiconductor chip 150 may be stacked on an upper surface of the third semiconductor chip 140. The fourth semiconductor chip 150 may include fourth bonding pads 152. The fourth bonding pads 152 may be arranged on a lower surface of the fourth semiconductor chip 150. The fourth bonding pads 152 may be electrically connected with the third plugs 144 via second fourth conductive bumps 166.

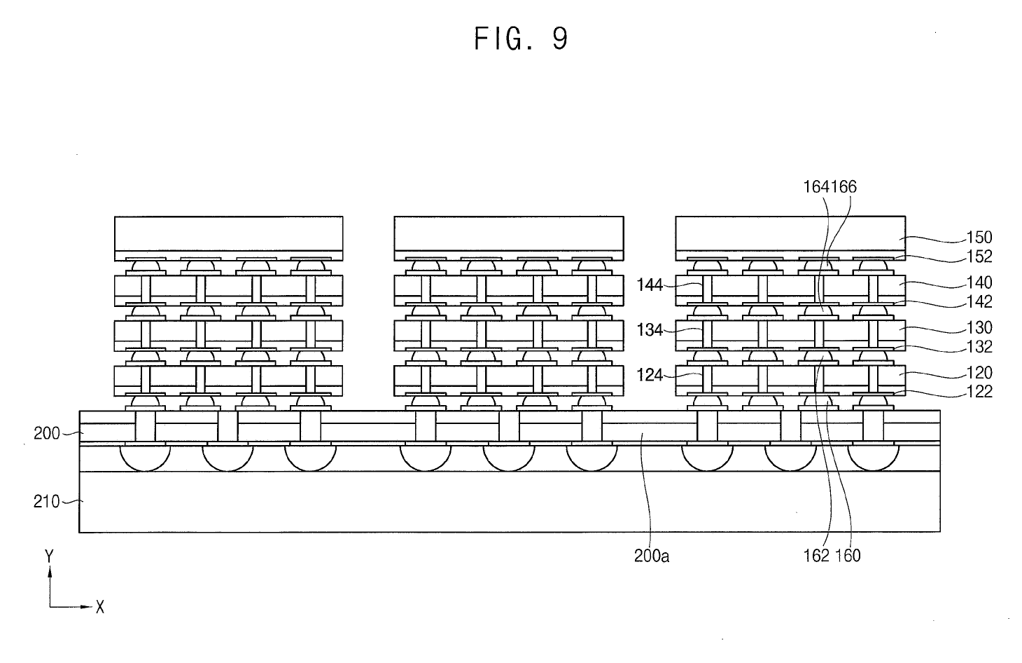

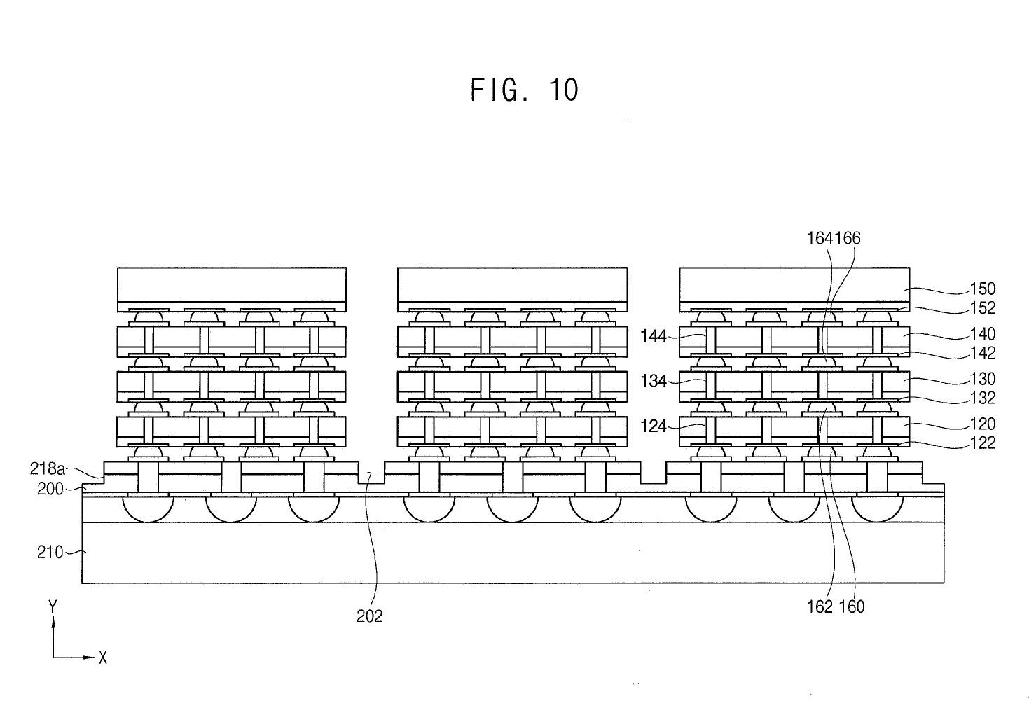

FIGS. 9 to 13 are cross-sectional views illustrating a method of manufacturing the semiconductor package in FIG. 8.

Referring to FIG. 9, the semiconductor chip 120, the second semiconductor chip 130, the third semiconductor chip 140 and the fourth semiconductor chip 150 may be sequentially attached to the upper surface of the wafer 200. The wafer 200 may be attached to an upper surface of a supporting substrate 210.

Referring to FIG. 10, portions 200a (FIG. 9) of the wafer 200 between the semiconductor chips 120, 130, 140 and 150 may be partially cut to form receiving grooves 202. Each of receiving grooves 202 may have a depth in the vertical direction that is less than a thickness of the wafer 200 in the vertical direction. Thus, side surfaces 218a of the wafer 200 may be exposed through the receiving grooves 202.

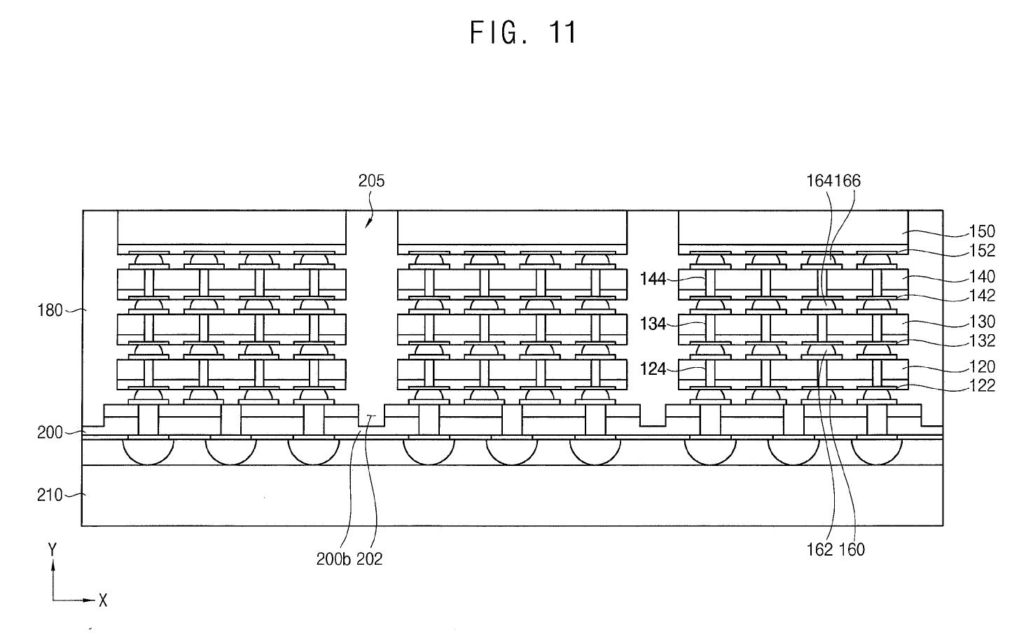

Referring to FIG. 11, the molding member 180 may be formed on the upper surface of the wafer 200. The molding member 180 may be configured to cover the semiconductor chips 120, the second semiconductor chip 130, the third semiconductor chip 140 and the fourth semiconductor chip 150. The molding member 180 may be configured to fill up spaces 206 between the semiconductor chips 120, 130, 140 and 150 and the receiving grooves 202. Because the molding member 180 may firmly support the semiconductor chips 120, 130, 140 and 150 and the wafer 200, the supporting substrate 210 may be separated from the wafer 200.

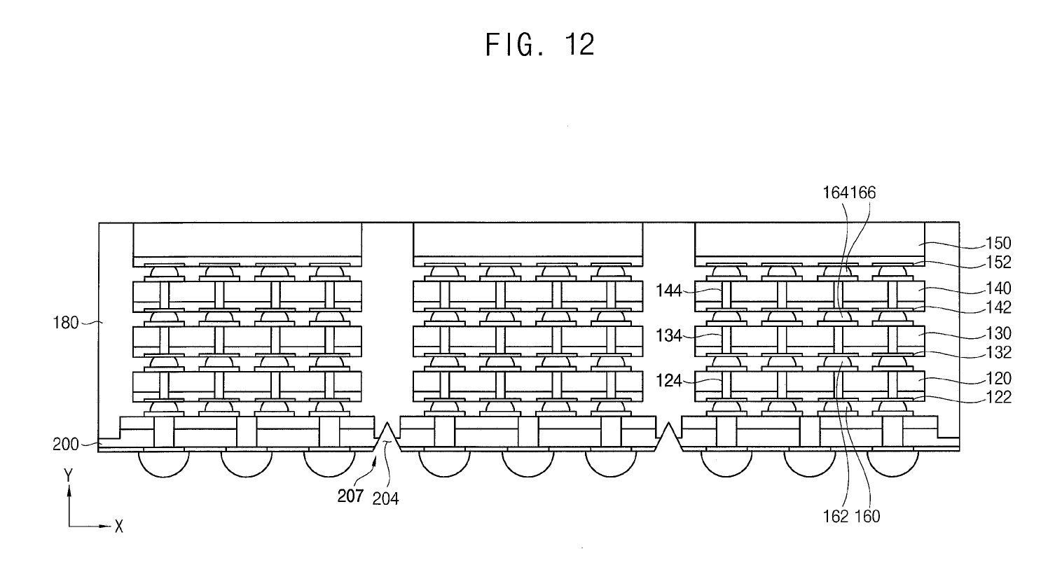

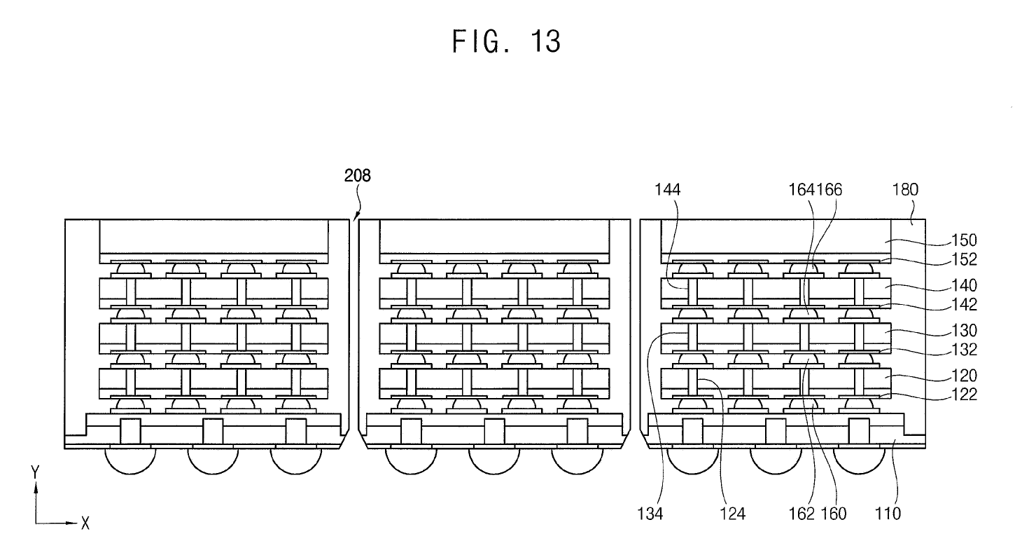

Referring to FIG. 12, after separating the supporting substrate 210 from the wafer 200, the portions of the wafer 200 in the lower spaces of receiving grooves 202 may be exposed at 207. The portions 200a (FIG. 11) of the wafer 200 in the lower spaces of the receiving grooves 202 and the molding member 180 in the receiving grooves 202 may be removed to form notches 204.

Each of the notches 204 may have an inverse V shape. Thus, the notch 204 may have a width in the horizontal direction that gradually decreases width from a lower end to an upper end in the notch 204. That is, the width in the horizontal direction of the lower portion of the notch 204 may be wider than a width of the receiving groove 202 at the vertex of the V shape. The protrusions 118 (FIG. 8) may be formed on the side surfaces of the wafer 200 by forming the inverse V-shaped notches 204. An inner surface of the inverse V-shaped notch 204 may correspond to the slant side surface 119 (FIG. 8) of the protrusion 118 and the slant side surface 184 of the molding member 180.

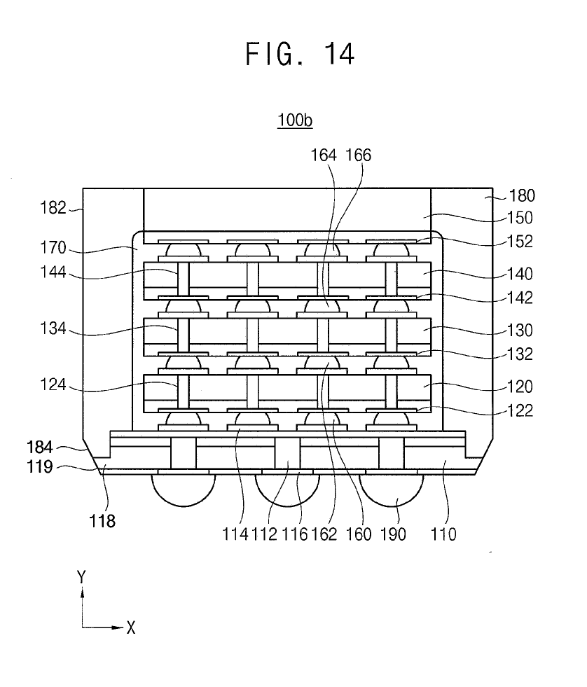

Referring to FIG. 13, the molding member 180 may be cut at 208 in the vertical direction from the upper end of the notch 204 to complete the semiconductor package 100a in FIG. 8.

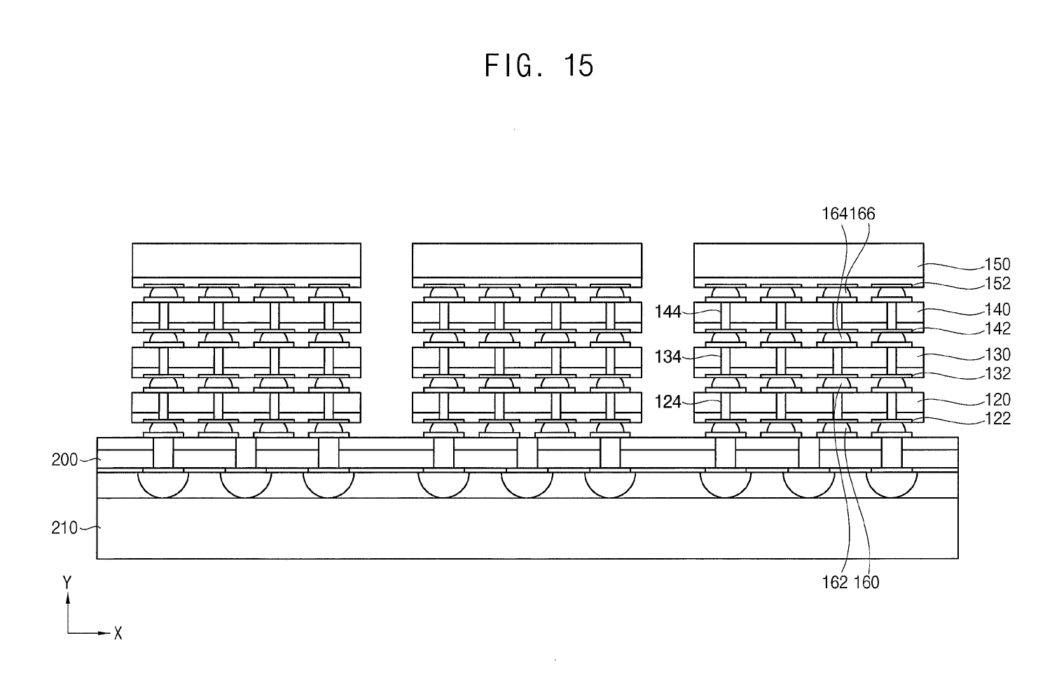

FIG. 14 is a cross-sectional view illustrating a semiconductor package in accordance with example embodiments.

A semiconductor package 100b of this example embodiment may include elements substantially the same as those of the semiconductor package 100a in FIG. 8, except that a molding member may be different. Thus, the same reference numerals may refer to the same elements and any further descriptions with respect to the same elements may be omitted herein for brevity.

Referring to FIG. 14, a semiconductor package 100b of this example embodiment may further include an inner molding portion 170. The inner molding portion 170 may be configured to surround the semiconductor chip 120, the second semiconductor chip 130, the third semiconductor chip 140 and the fourth semiconductor chip 150. The inner molding portion 170 may have an outer surface that protrudes from the side surfaces of the semiconductor chips 120, 130, 140 and 150.

The molding member 180 may be formed on the upper surface of the wafer 200. The molding member 180 may be configured to surround the inner molding portion 170. The molding member 180 may correspond to an outer molding portion configured to surround the inner molding portion 170. The inner molding portion 170 may include a first insulating material. The outer molding portion 180 may include a second insulating material. The first insulating material and the second insulating material may include substantially the same material. Alternatively, the first insulating material and the second insulating material may include different materials.

FIGS. 15 to 20 are cross-sectional views illustrating a method of manufacturing the semiconductor package in FIG. 14.

Referring to FIG. 15, the semiconductor chip 120, the second semiconductor chip 130, the third semiconductor chip 140 and the fourth semiconductor chip 150 may be sequentially attached to the upper surface of the wafer 200. The wafer 200 may be attached to an upper surface of a supporting substrate 210.

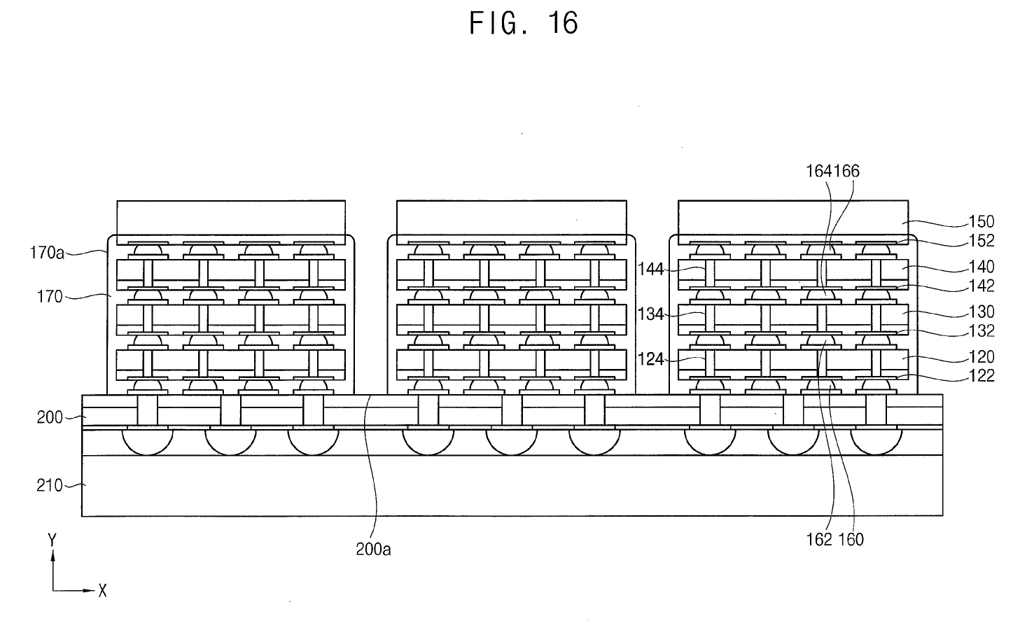

Referring to FIG. 16, the inner molding portion 170 may be formed on the side surfaces of the semiconductor chips 120, 130, 140 and 150. The outer surface 170a of the inner molding portion 170 may protrude from the side surfaces of the semiconductor chips 120, 130, 140 and 150. That is, the outer surface 170a of the inner molding portion 170 may extend in a horizontal direction beyond the side surfaces of the semiconductor chips 120, 130, 140 and 150. Thus, portions 200b of the wafer 200 between the semiconductor chips 120, 130, 140 and 150 may be exposed.

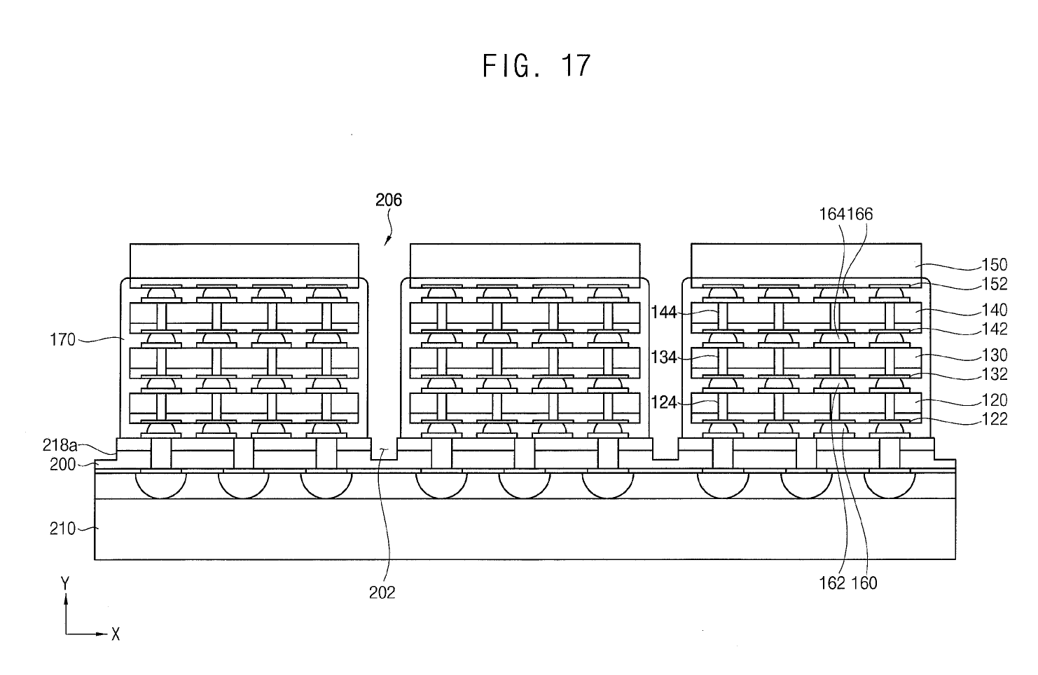

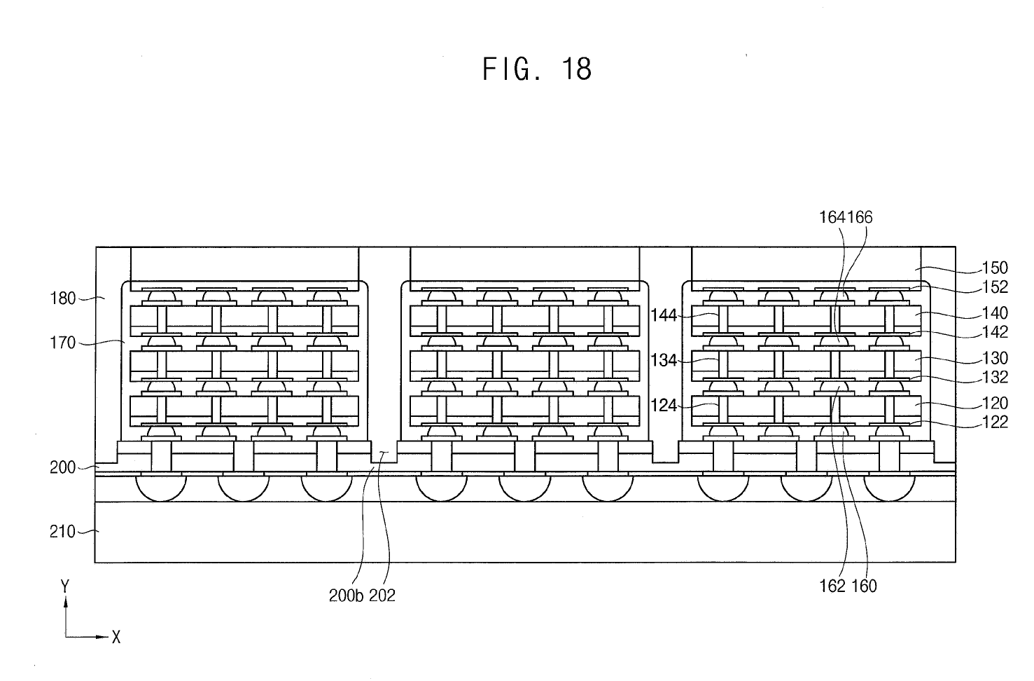

Referring to FIG. 17, the portions 200a (FIG. 16) of the wafer 200 between the semiconductor chips 120, 130, 140 and 150 may be partially cut to form receiving grooves 202. Each of receiving grooves 202 may have a depth in the vertical direction that is less than a thickness of the wafer 200 in the vertical direction. Thus, side surfaces 218a of the wafer 200 may be exposed through the receiving grooves 202.

Referring to FIG. 18, the molding member 180 may be formed on the upper surface of the wafer 200. The molding member 180 may be configured to surround the inner molding portion 170. The molding member 180 may be configured to fill up spaces 206 (FIG. 17) between the semiconductor chips 120, 130, 140 and 150 and the receiving grooves 202. The molding member 180 may correspond to the outer molding portion configured to surround the inner molding portion 170. The inner molding portion 170 and the outer molding portion 180 may include substantially the same material. Alternatively, the inner molding portion 170 and the outer molding portion 180 may include different materials.

Because the inner molding portion 170 and the outer molding portion 180 may firmly support the semiconductor chips 120, 130, 140 and 150 and the wafer 200, the supporting substrate 210 may be separated from the wafer 200.

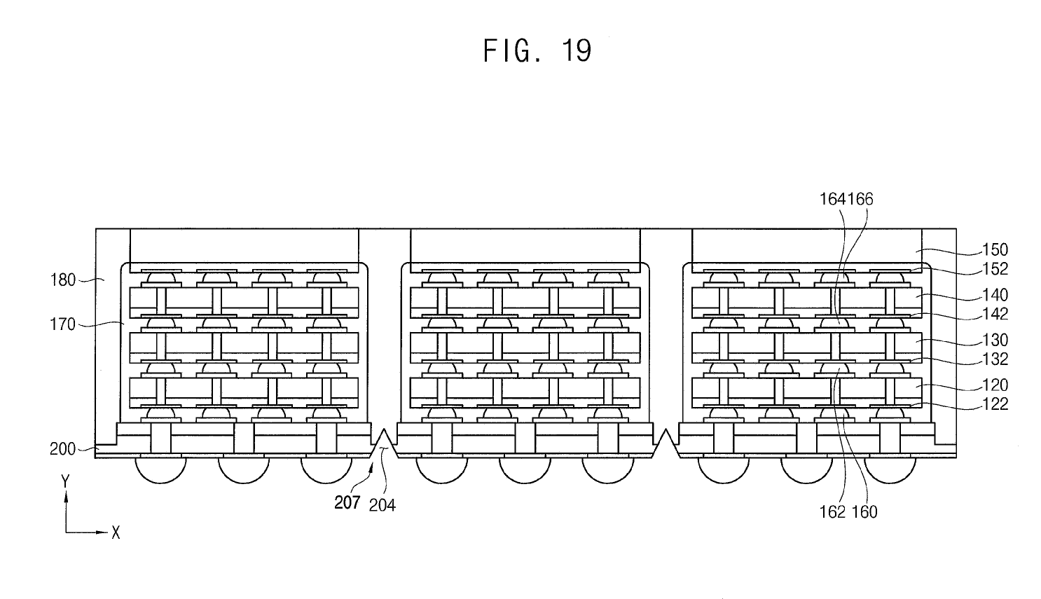

Referring to FIG. 19, after separating the supporting substrate 210 from the wafer 200, the portions of the wafer 200 in the lower spaces of receiving grooves 202 may be exposed at 207. The portions 200b (FIG. 18) of the wafer 200 in the lower spaces of the receiving grooves 202 and the molding member 180 in the receiving grooves 202 may be removed to form notches 204.

Each of the notches 204 may have an inverse V shape. Thus, the notch 204 may have a width in the horizontal direction that gradually decreases from a lower end to an upper end in the notch 204. That is, the width in the horizontal direction of the lower portion of the notch 204 may be wider than a width of the receiving groove 202 at the vertex of the V shape. The protrusions 118 (FIG. 14) may be formed on the side surfaces of the wafer 200 by forming the inverse V-shaped notches 204. An inner surface of the inverse V-shaped notch 204 may correspond to the slant side surface 119 (FIG. 14) of the protrusion 118 and the slant side surface 184 of the molding member 180.

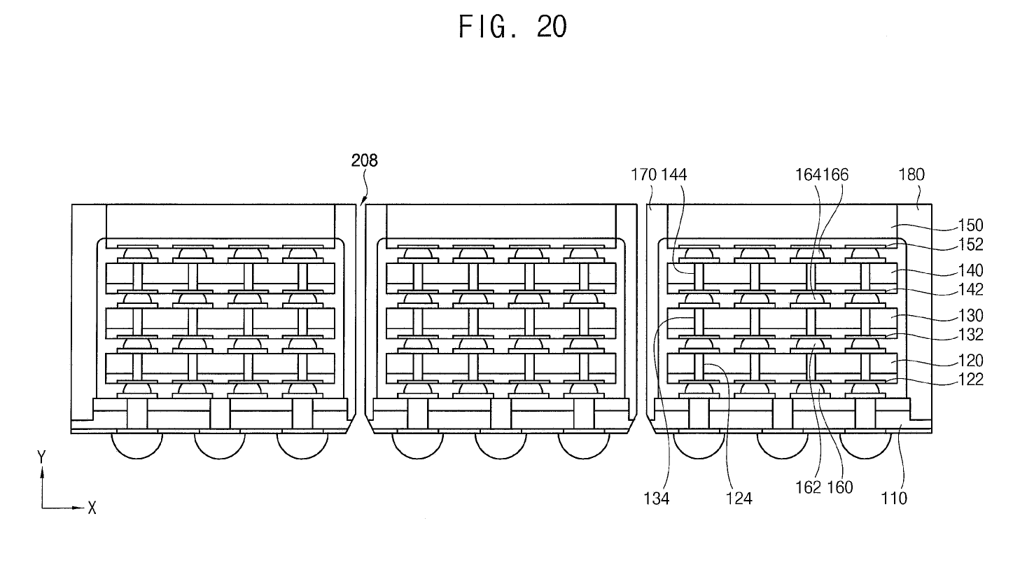

Referring to FIG. 20, the molding member 180 may be cut at 208 in the vertical direction from the upper end of the notch 204 to complete the semiconductor package 100b in FIG. 14.

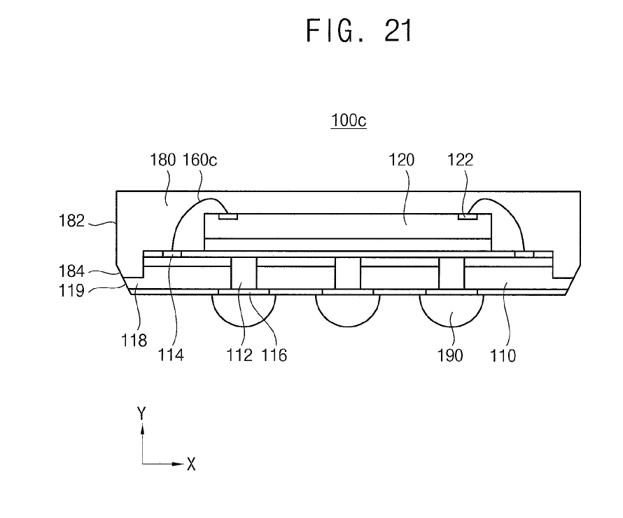

FIG. 21 is a cross-sectional view illustrating a semiconductor package in accordance with example embodiments.

A semiconductor package 100c of this example embodiment may include elements substantially the same as those of the semiconductor package 100 in FIG. 1, except for an electrical connection between the semiconductor chip 120 and the package substrate 110. Thus, the same reference numerals may refer to the same elements and any further description with respect to the same elements may be omitted herein for brevity.

Referring to FIG. 21, bonding pads 122 may be arranged on the upper surface of the semiconductor chip 120. Thus, the upper surface of the semiconductor chip 120 may correspond to the active face.

Conductive wires 160c may be electrically connected between the bonding pads 122 of the semiconductor chip 120 and the upper pads 114 of the package substrate 110. The conductive wires 160c may be covered with the molding member 180.

A method of manufacturing the semiconductor package 100c may include processes substantially the same as those illustrated with reference to FIGS. 3 to 7 except for including a wire bonding process in place of the bump bonding process. Thus, descriptions with respect to the method of manufacturing the semiconductor package 100c may be omitted herein for brevity.

The semiconductor chip 100c may further include at least one semiconductor chip stacked on the semiconductor chip 120. The stacked semiconductor chip may be electrically connected with the semiconductor chip 120 through the conductive wires 160c. A method of manufacturing the semiconductor package including at least two semiconductor chips may include processes substantially the same as those illustrated with reference to FIGS. 9 to 13 or

FIGS. 15 to 20 except for including a wire bonding process in place of the bump bonding process. Thus, illustrations with respect to the method of manufacturing the semiconductor package including at least two semiconductor chips may be omitted herein for brevity.

According to example embodiments, the molding member 180 on the protrusion of the package substrate 118 may be configured to cover the side surface of the package substrate so that the side surface of the package substrate may not be exposed. Thus, electrical, physical and/or chemical damages to the side surface of the package substrate may be suppressed.

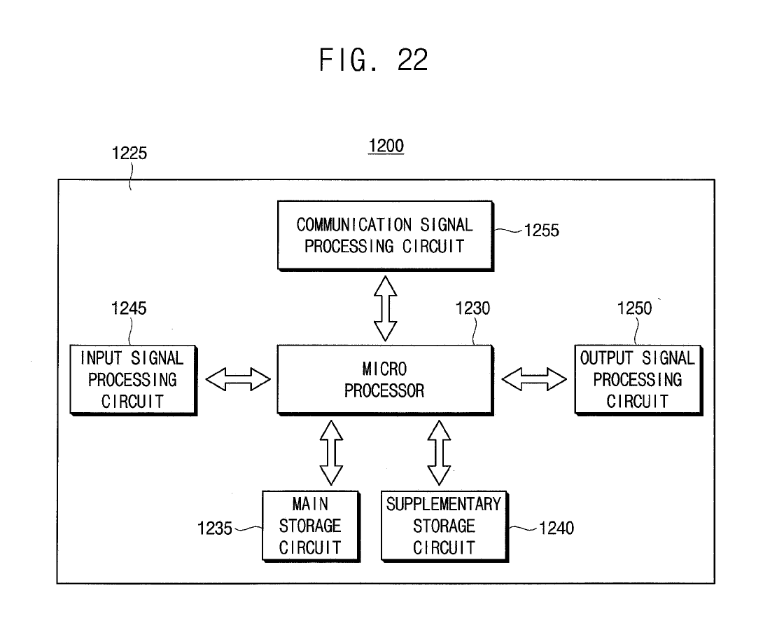

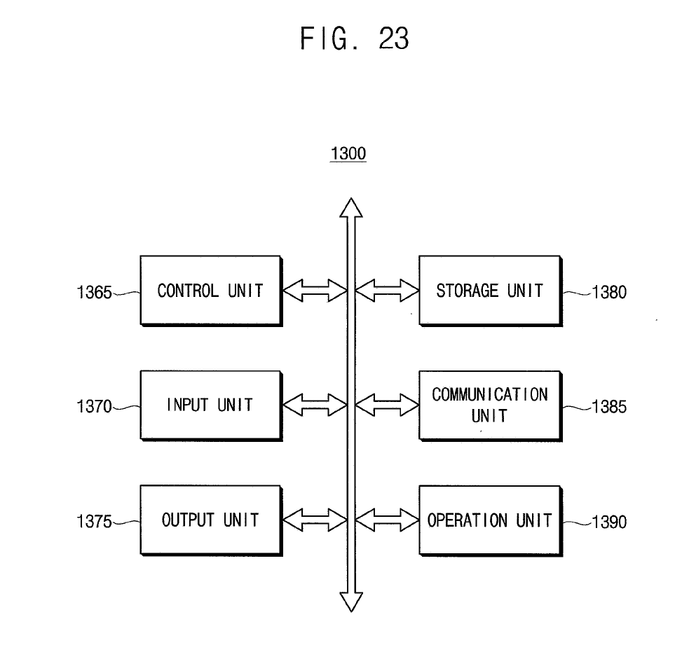

FIG. 22 is a block diagram schematically illustrating an electronic circuit board 1200 including a semiconductor package according to an example embodiment.

In detail, the electronic circuit board 1200 may include a microprocessor 1230 disposed on a circuit board 1225, a main storage circuit 1235 and a supplementary storage circuit 1240 that communicate with the microprocessor 1230, an input signal processing circuit 1245 that transfers a command to the microprocessor 1230, an output signal processing circuit 1250 that receives a command from the microprocessor 1230, and a communication signal processing unit 1255 that exchanges an electrical signal with other circuit boards. It may be understood that each of arrows refers to a path through an electrical signal is transferred.

The microprocessor 1230 may receive and process various electrical signals to output a result of the processing and may control the other elements of the electronic circuit board 1200. It may be understood that the microprocessor 1230 is, for example, a central processing unit (CPU) and a main control unit (MCU).

The main storage circuit 1235 may temporarily store data, which is always or frequently required by the microprocessor 1230, before-processing data, and after-processing data. The main storage circuit 1235 may need a fast response, and thus may be configured with a semiconductor memory chip. In detail, the main storage circuit 1235 may be a semiconductor memory called a cache. The main storage circuit 1235 may be configured with static random access memory (SRAM), dynamic random access memory (DRAM), resistive random access memory (RRAM), and application semiconductor memories thereof (for example, a utilized RAM, a ferro-electric RAM, a fast cycle RAM, a phase changeable RAM, a magnetic RAM, and/or the like) or may be configured with other semiconductor memories.

In addition, the main storage circuit 1235 may include a random access memory (RAM) irrespective of volatility/non-volatility. In the present embodiment, the main storage circuit 1235 may include one or more semiconductor chips, semiconductor packages, or semiconductor modules according to the exemplary embodiments. The supplementary storage circuit 1240 may be a large-capacity storage element and may be configured with a nonvolatile semiconductor memory, such as flash memory or the like, or a hard disk drive using a magnetic field. Alternatively, the supplementary storage circuit 1240 may be configured with a compact disk drive using light. Although the supplementary storage circuit 1240 does not desire a fast speed in comparison with the main storage circuit 1235, the supplementary storage circuit 1240 may be applied to a case of desiring to store large-scale data. The supplementary storage circuit 1240 may include a nonvolatile storage element irrespective of random/nonrandom.

The supplementary storage circuit 1240 may include the semiconductor chip, the semiconductor package, or the semiconductor module according to the example embodiments disclosed herein. The input signal processing circuit 1245 may convert an external command into an electrical signal or may transfer an electrical signal, transferred from the outside, to the microprocessor 1230.

A command or an electrical signal transferred from the outside may be an operation command, an electrical signal that is to be processed, or data that are to be stored. The input signal processing circuit 1245 may be a terminal signal processing circuit that processes a signal transmitted from a keyboard, a mouse, a touch pad, an image recognition device, or various sensors, an image signal processing circuit that processes an image signal transferred from a scanner or a camera, various sensors, an input signal interface, or the like. The input signal processing circuit 1245 may include the semiconductor chip, the semiconductor package, or the semiconductor module according to the example embodiments disclosed herein.

The output signal processing circuit 1250 may be an element for transmitting an electrical signal, generated through processing by the microprocessor 1230, to the outside. For example, the output signal processing circuit 1250 may be a graphic card, an image processor, an optical converter, a beam panel card, one of various functional interface circuits, or the like. The output signal processing circuit 1250 may include the semiconductor package according to the example embodiments disclosed herein.

The communication circuit 1255 may be an element for directly exchanging an electrical signal with other electronic systems or other circuit boards without undergoing the input signal processing circuit 1245 or the output signal processing circuit 1250. For example, the communication circuit 1255 may include a modem, a LAN card, various interfaces, and/or the like of a personal computer (PC) system. The communication circuit 1255 may include the semiconductor package according to the example embodiments disclosed herein.

FIG. 23 is a block diagram schematically illustrating an electronic system 1300 according to an example embodiment disclosed herein.

In detail, the electronic system 1300 according to an exemplary embodiment may include a control unit 1365, an input unit 1370, an output unit 1375, and a storage unit 1380. Also, the electronic system 1300 may further include a communication unit 1385 and/or an operation unit 1390.

The control unit 1365 may overall control the electronic system 1300 and elements.

The control unit 1365 may be understood as a CPU or a central control unit, and may include the electronic circuit board 1200 (see FIG. 22) according to an exemplary embodiment disclosed herein. Also, the control unit 1365 may include the semiconductor package according to the example embodiments disclosed herein.

The input unit 1370 may transfer an electrical command signal to the control unit 1365. The input unit 1370 may be a keyboard, a keypad, a touch pad, an image recognizer such as a scanner, or various input sensors. The input unit 1370 may include the semiconductor package according to the example embodiments disclosed herein.

The output unit 1375 may receive the electrical command signal from the control unit 1365 to output a result of processing by the electronic system 1300. The output unit 1375 may be a monitor, a printer, a beam irradiator, or one of various mechanical devices. The output unit 1375 may include the semiconductor package according to the example embodiments disclosed herein.

The storage unit 1380 may be an element for temporarily or permanently storing an electrical signal, which is to be processed by the control unit 1165, and an electrical signal generated through processing by the control unit 1165. The storage unit 1380 may be physically or electrically connected or coupled to the control unit 1365. The storage unit 1380 may be a semiconductor memory, a magnetic storage device such as a hard disk or the like, an optical storage device such as a compact disk or the like, a server having a data storing function, or the like. Also, the storage unit 1380 may include the semiconductor package according to the example embodiments disclosed herein.

The communication unit 1385 may receive an electrical command signal from the control unit 1365 and may transfer the electrical command signal to another electronic system, or may receive an electrical command signal from the other electronic system. The communication unit 1385 may be a modem, a wired transmission/reception device such as an LAN card, a wireless transmission/reception device such as a Wibro interface, an infrared port, or the like. Also, the communication unit 1385 may include the semiconductor package according to the example embodiments disclosed herein.

The operation unit 1390 may perform a physical or mechanical operation according to a command of the control unit 1365. For example, the operation unit 1390 may be an element, which performs a mechanical operation, such as a plotter, an indicator, an up/down operation, or the like. The electronic system 1300 according to an exemplary embodiment may include a computer, a network server, a networking printer, or a scanner, a wireless controller, a mobile communication terminal, an exchanger, an electronic device performs a programmed operation, and/or the like.

Moreover, the electronic system 1300 may be applied to mobile phones, MP3 players, navigation devices, portable multimedia players (PMPs), solid state disks (SSDs), household appliances, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents, but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor package, comprising:
a package substrate including a protrusion formed on a side surface of the package substrate;
a semiconductor chip arranged on an upper surface of the package substrate and electrically connected with the package substrate; and
a molding member formed on the upper surface and the side surface of the package substrate and an upper surface of the protrusion.

2. The semiconductor package of claim 1, wherein the protrusion is formed on a lower portion of the side surface of the package substrate.

3. The semiconductor package of claim 2, wherein the protrusion has a slant side surface.

4. The semiconductor package of claim 3, wherein a portion of the molding member on the upper surface of the protrusion has a slant side surface that is substantially coplanar with the slant side surface of the protrusion.

5. The semiconductor package of claim 1, wherein the molding member has an outer surface protruded from an outer surface of the protrusion.

6. The semiconductor package of claim 1, wherein the molding member comprises:
an inner molding portion configured to surround the semiconductor chip; and
an outer molding portion formed on surround the upper surface and the side surface of the package substrate and the upper surface of the protrusion to surround the inner molding portion.

7. The semiconductor package of claim 6, wherein the inner molding portion comprises a first insulating material and the outer molding portion comprises a second insulating material that is different from the first insulating material.

8. The semiconductor package of claim 1, wherein the semiconductor chip comprises a plug formed in the semiconductor chip,
the semiconductor package further comprising:
a second semiconductor chip stacked on the semiconductor chip; and
a conductive bump interposed between the semiconductor chip and the second semiconductor chip to electrically connect the plug with the second semiconductor chip.

9. A method of manufacturing a semiconductor package, the method comprising:
arranging a plurality of first semiconductor chips on an upper surface of a wafer;
forming a receiving groove at a portion of the wafer between the first semiconductor chips;
filling spaces between the first semiconductor chips and the receiving groove with a molding member;
removing a portion of the wafer under the receiving groove and a portion of the molding member to form a notch; and
cutting the molding member along the notch.

10. The method of claim 9, further comprising:
attaching the wafer to a supporting substrate; and
separating the supporting substrate from the wafer before forming the notch.

11. The method of claim 9, wherein the notch has an inverse V shape.

12. The method of claim 11, wherein the inverse V-shaped notch has a lower width that is greater than a width at a vertex of the V-shaped notch.

13. The method of claim 9, further comprising surrounding the first semiconductor chip with an inner molding portion.

14. The method of claim 9, further comprising stacking a second semiconductor chip on the first semiconductor chip.

15. The method of claim 14, wherein stacking the second semiconductor chip on the first semiconductor chip comprises electrically connecting a plug of the first semiconductor chip with the second semiconductor chip using a conductive bump.

16. A semiconductor package, comprising:
a package substrate comprising an upper surface, a first side and a second side that is opposite the first side, the first side comprising a first protuberance that extends from the first side in a direction that is substantially parallel to the upper surface of the package substrate, and the second side comprising a second protuberance that extends from the second side in a direction that is substantially parallel to the upper surface of the package substrate, the first and second protuberances each comprising an upper surface;
a first semiconductor chip disposed on the upper surface of the package substrate; and
a mold member formed on the upper surface of the package substrate to cover the upper surface, the first side and the second side of the package substrate and the upper surface of each of the first and second protuberances.

17. The semiconductor package according to claim 16, wherein the first and second protuberances each comprise an edge surface that is angled with respect to the upper surface of the package substrate.

18. The semiconductor package according to claim 17, wherein the mold member comprises a first surface that is substantially coplanar with the angled edge surface of the first protuberance and a second surface that is substantially coplanar with the angle edge of the second protuberance.

19. The semiconductor package according to claim 18, wherein the molding member comprises a first molding portion and a second molding portion, the first molding portion being configured to surround the first semiconductor chip and the second molding portion being configured to surround the first molding portion.

20. The semiconductor package according to claim 16, wherein the first semiconductor chip is electrically connected to the package substrate by at least one conductive bump.
